(19) United States
(12) Patent Application Publication
(10) Pub. No.: US 2022/0184772 A1
(43) Pub. Date: Jun. 16, 2022

(54) METHOD AND APPARATUS FOR DOUBLE-SIDE POLISHING WORK

(71) Applicant: SUMCO Corporation, Tokyo (JP)

(72) Inventor: Yuji MIYAZAKI, Tokyo (JP)

(73) Assignee: SUMCO Corporation, Tokyo (JP)

(21) Appl. No.: 17/440,082

(22) PCT Filed: Dec. 26, 2019
(86) PCT No.: PCT/JP2019/051215

§ 371 Date: Sep. 16, 2021

(30) Foreign Application Priority Data
Mar. 22, 2019 (JP) 2019-055545

(51) Int. Cl. B24B 37/08

(52) U.S. Cl. CPC B24B 37/08

(57) ABSTRACT

A double-side polishing method for a work includes: a pre-polishing index calculation step of calculating an index Xp for a work having been subjected to double-side polishing in the last batch; a target polishing time calculation step of calculating a target polishing time of the current batch using a predetermined prediction formula; and a double-side polishing step of performing double-side polishing of a work using the target polishing time. A double-side polishing apparatus for a work includes: a measurement unit for measuring thicknesses of a work having been subjected to double-side polishing in the last batch; a first calculation unit calculating an index Xp; a second calculation unit calculating a target polishing time Tt of the current batch using a predetermined prediction formula; and a control unit controlling double-side polishing of the work using the calculated target polishing time Tt.

### TECHNICAL FIELD

This disclosure relates to a method of double-side polishing a work and a double-side polishing apparatus for a work.

### BACKGROUND

Conventionally, in order to increase the planarity of a work such as a silicon wafer, double-side polishing for simultaneously polishing front and back surfaces of a work sandwiched between upper and lower plates each provided with a polishing pad has been performed. For example, WO 2014/002467 A (PTL 1) proposes a technique of controlling the amount of polishing removal of a work.

### CITATION LIST

### Patent Literature

PTL 1: WO 2014/002467 A

### SUMMARY

### Technical Problem

In double-side polishing, GBIR values sometimes vary between batches; accordingly, there has been a demand for controlling the variation.

It could therefore be helpful to provide a double-side polishing method for a work and a double-side polishing apparatus for a work, which make it possible to control the variation of the GBIR values of polished works between batches.

### Solution to Problem

This disclosure primarily includes the following features.

A method of double-side polishing a work, the method includes:

a pre-polishing index calculation step of measuring thicknesses of a work having been subjected to double-side polishing in the last batch at a plurality of measurement points in a plane of the work using a measurement unit, and calculating an index Xp determined by integrating the thicknesses of the work measured at the plurality of measurement points in the plane of the work by a first calculation unit;

a target polishing time calculation step of calculating a target polishing time Tt of a current batch by a second calculation unit using a predetermined prediction formula describing a relation between a target polishing time Tt of the current batch, the index Xp calculated in the pre-polishing index calculation step, and an index Xt set as a target in the last batch; and

a double-side polishing step of performing double-side polishing of a work while controlling the double-side polishing by a control unit using the target polishing time Tt calculated in target polishing time calculation step.

Note that “measuring thickness of work” herein includes measuring parameters having a correlation with the thickness of a work and then calculating the thickness of the work from the parameters, as well as directly measuring the thickness of the work.

Further, “GBIR value” means the GBIR specified in the SEMI M1 and SEMI MF1530.

In the above method, the index Xp is preferably determined by integrating the thicknesses of the work measured at the plurality of measurement points on one of two coordinate axes on the plane of the work and further integrating the thicknesses on the other coordinate axis.

In the above method, preferably, the two coordinate axes consist of a coordinate axis in a radial direction of the work and a coordinate axis in a circumferential direction of the work, and

the index Xp is determined by integrating the thicknesses of the work measured at the plurality of measurement points in the circumferential direction of the work, and further integrating the thicknesses in radial directions of the work.

In a method of double-side polishing a work, according to this disclosure, the index Xp is preferably calculated by:

dividing the plane of the work into a plurality of local planes each including one or more of the measurement points,

calculating thicknesses of the work at the local planes based on the thicknesses of the work measured at the measurement points included in the plurality of local planes, and

integrating the calculated thicknesses of the work at the local planes in the plane of the work.

In the above method, the thickness of the local planes of the work is preferably an average of the thicknesses of the work measured at the measurement points defining the local planes.

In a method of double-side polishing a work, according to this disclosure, the measurement points are preferably positioned at regular intervals on at least one of two coordinate axes in the plane of the work.

In a method of double-side polishing a work, according to this disclosure, preferably, the predetermined prediction formula is represented by:

A1×Tt^{α}=A2×Xp^{β}+A3×Xt^{γ}+A4,

where each of A1, A2, A3, A4, α, β, and γ is one of a coefficient found by regression analysis and a predetermined coefficient determined previously, and

at least one of A1, A2, A3, A4, α, β, and γ is a coefficient found by regression analysis.

In a method of double-side polishing a work, according to this disclosure, the double-side polishing step is preferably performed using a batch-processing double-side polishing apparatus for works, the apparatus comprising: rotating plates having an upper plate and a lower plate; a sun gear provided at a center portion of the rotating plates; an internal gear provided on a periphery of the rotating plates; and a carrier plate having one or more retainer openings each for holding a work, the carrier plate being provided between the upper plate and the lower plate, with a polishing pad being attached to each of a lower surface of the upper plate and an upper surface of the lower plate.

In a method of double-side polishing a work, according to this disclosure, the double-side polishing step preferably comprises a step of polishing both surfaces of the work while supplying a polishing slurry to the polishing pads and relatively rotating the rotating plates and the carrier plate for the calculated polishing time of the current batch.

In a method of double-side polishing a work, according to this disclosure, the work is preferably a wafer.

A double-side polishing apparatus for a work, according to this disclosure preferably includes:

rotating plates having an upper plate and a lower plate; a sun gear provided at a center portion of the rotating plates; an internal gear provided on a periphery of the rotating plates; a carrier plate having one or more retainer openings each for holding a work, the carrier plate being provided between the upper plate and the lower plate; with a polishing pad being attached to each of a lower surface of the upper plate and an upper surface of the lower plate, the apparatus further comprising:

a measurement unit for measuring thicknesses of the work having been subjected to double-side polishing in a last batch;

a first calculation unit calculating an index Xp by integrating the measured thicknesses of the work in the plane of the work;

a second calculation unit calculating a target polishing time Tt of a current batch, using a predetermined prediction formula describing a relation between the target polishing time Tt of the current batch, the index Xp, and an index Xt set as a target in the last batch; and

a control unit controlling double-side polishing of the work using the calculated target polishing time Tt.

### Advantageous Effect

This disclosure can provide a double-side polishing method for a work and a double-side polishing apparatus for a work, which make it possible to control the variation of the GBIR values of polished wafers between batches.

### BRIEF DESCRIPTION OF THE DRAWINGS

In the accompanying drawings:

FIG. 1 is a front view of a double-side polishing apparatus for a work, according to an embodiment of this disclosure;

FIG. 2 is a flowchart illustrating a method of polishing both sides of a work, according to an embodiment of this disclosure;

FIG. 3 is a diagram illustrating the relationship between the radial positions of measurement points from the center of the wafer, at which the thicknesses of a wafer are measured, and the thicknesses of the wafer obtained by averaging the thicknesses of the wafer in the circumferential direction;

FIG. 4 is a flowchart illustrating a double-side polishing method for a work, according to another embodiment of this disclosure;

FIG. 5 is a diagram illustrating a method of calculating a reference plane;

FIG. 6 is a diagram illustrating a method of calculating the wafer thickness of each local plane; and

FIG. 7 is a diagram illustrating the relationship between indices and the GBIR.

### DETAILED DESCRIPTION

Embodiments of an apparatus and a method for double-side polishing a work, according to this disclosure will now be described in detail with reference to the drawings.

<Double-Side Polishing Apparatus for Work>

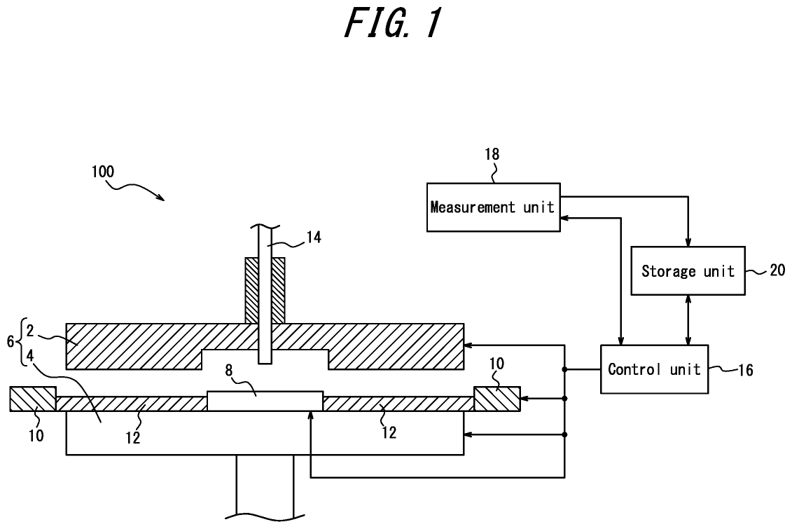

FIG. 1 is a front view of a double-side polishing apparatus for a work, according to an embodiment of this disclosure. As illustrated in FIG. 1, a double-side polishing apparatus 100 includes rotating plates 6 having an upper plate 2 and a lower plate 4; a sun gear 8 provided at a center portion of the rotatable plates 6; an internal gear 10 provided on a circumference of the rotating plates 6; and a carrier plate 12 that is provided between the upper plate 2 and the lower plate 4 and has one or more retainer openings (not illustrated) for holding work(s) (wafers in this example). Further, a polishing pad (not illustrated) is attached to each of the bottom surface of the upper plate 2 and the upper surface of the lower plate 4. In the double-side polishing apparatus 100, a slurry supply mechanism 14 for supplying a polishing slurry is provided at a center portion of the upper plate 2.

As illustrated in FIG. 1, the double-side polishing apparatus 100 further includes a control unit 16, a measurement unit 18, and a storage unit 20.

The control unit 16 has a controller unit (controller) controlling the rotation of the upper plate 2, the lower plate 4, the sun gear 8, and the internal gear 10; a first calculation unit (first calculator) calculating an index Xp by integrating the measured thicknesses of the wafer in the plane of the wafer (details will be described below); a second calculation unit (second calculator) calculating a target polishing time Tt of the current batch using a predetermined prediction formula that is a relation of the target polishing time Tt of the current batch, the index Xp, and an index Xt set as a target in the last batch (details will be described below); and a determination unit (processor) performing determination whether the batch process is to be terminated or not. The first calculation unit and the second calculation unit may constitute separate units or one and the same unit. As described below, the above controller unit is configured to also control double-side polishing of a wafer using the calculated target polishing time Tt. Note that the control unit 16 can be implemented by a central processing unit (CPU) in a computer.

The measurement unit 18 is not limited and can be implemented, for example, by a spectral interference displacement sensing device, and is used to measure the thickness of a wafer having been subjected to double-side polishing in the last batch at each measurement point.

The storage unit 20 stores the target polishing time, the measured thicknesses of a wafer, the indices Xp and Xt to be described, etc. Here, the storage unit 20 may be a known given memory, and can be implemented by, for example, a hard disk, a ROM, or a RAM.

<Double-Side Polishing of Work>

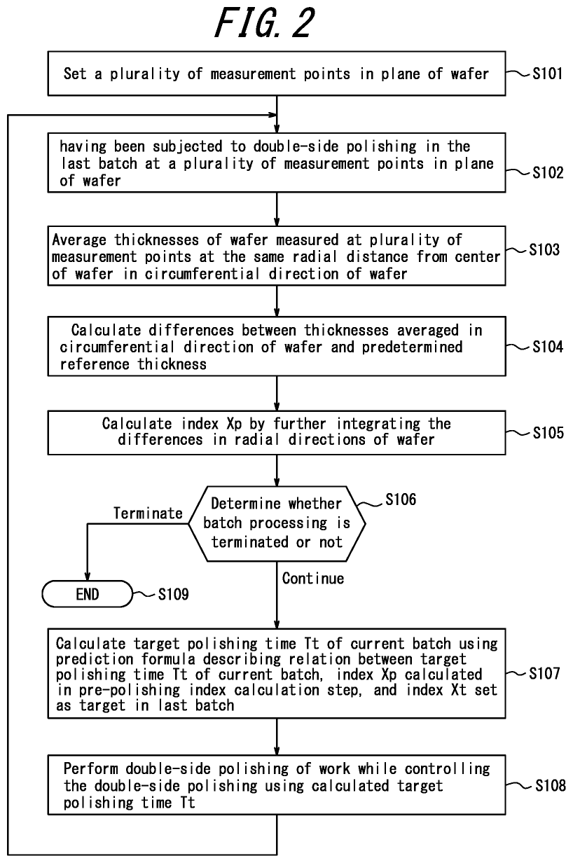

FIG. 2 is a flowchart illustrating a method of polishing both sides of a work, according to an embodiment of this disclosure. The method of double-side polishing a work, according to one embodiment of this disclosure, illustrated in FIG. 2 can be performed using, for example, the double-side polishing apparatus for a work, according one embodiment of this disclosure, illustrated in FIG. 1. Next, a double-side polishing method for a work, according to an embodiment of this disclosure will be described with reference to FIGS. 1 and 2.

In this embodiment, a wafer (a silicon wafer in this example) is used as a work (hereinafter, described as a wafer).

As illustrated in FIG. 2, first, a plurality of measurement points in the plane of the wafer are set by the measurement unit 18 (Step S101). In this embodiment, two coordinate axes are set in the plane of the wafer, and in this example, the two coordinate axes have a coordinate axis in a radial direction of the wafer and a coordinate axis in a circumferential direction of the wafer.

In this embodiment, a plurality of measurement points are set in the plane of a wafer to have different radial distances from the center of the wafer; further, a plurality of measurement points are set in the plane of the wafer to have the same radial distance from the center of the wafer in the circumferential direction of the wafer. The measurement points in the plane of the wafer are preferably set to be uniformly distributed in the plane of the wafer. The setting of the measurement points in this embodiment will now be described in more detail.

In this example, the measurement points are set on a wafer having a diameter of 300 mm at regular intervals of 1 mm in the radial directions from the center of the wafer in a region of radial distances of 0 mm to 148 mm (excluding a region of 2 mm in the inward radial direction of the wafer from the outer edge of the wafer, since the thickness of this region is usually reduced by beveling of the wafer). In this example, the center of the wafer is also set as a measurement point.

Note that the above intervals are not necessarily 1 mm, and may be variously set depending on the diameter of the wafer, or the like. Further, the measurement points are preferably set to be positioned at regular intervals in the radial directions as in this example, and yet may be set at irregular intervals.

Further, in this example, the measurement points are set at regular intervals of 1° in the circumferential direction of the wafer on the entire circumference of the wafer.

Note that the above intervals are not necessarily 1°, and may be variously set. Further, the measurement points are preferably set to be positioned at regular intervals in the circumferential direction, yet may be set at irregular intervals.

Accordingly, in this example, the number of the measurement points to be set is 148×2×360+1=106561 in total including the center of the wafer. Namely, in this example, the measurement points are set on the entire region of the wafer excluding the above region of which thickness has been reduced by beveling (in this example, at regular intervals of 1 mm in the radial direction, 1° in the circumferential direction).

Next, as illustrated in FIG. 2, in this embodiment, the thicknesses of the wafer are measured at the plurality of measurement points in the plane of a wafer having been subjected to double-side polishing in the last batch (Step S102: part of a pre-polishing index calculation step).

In this embodiment, the thicknesses of the wafer are measured at all the 106561 measurement points.

As illustrated in FIG. 1, in this example, the thicknesses of the wafer can be measured at all the above measurement points by the measurement unit 18 (the spectral interference displacement sensing device in this example) after double-side polishing in the last batch.

Specifically, the spectral interference displacement sensing device has a first sensor unit (not illustrated) performing measurement on the front surface of the wafer; a second sensor unit (not illustrated) that is provided to face the first sensor unit and performs measurement on the back surface of the wafer; and a computing unit (not illustrated). The spectral interference displacement sensing device performs the following measurements.

The first sensor unit and the second sensor unit emit light of a wide wavelength band toward the measurement points on the front and back surfaces of the wafer, and reflected light is received by the centers. After that, the reflected light received by the sensor units is analyzed by the computing unit, thereby calculating the thickness of the wafer at each measurement point.

The measured thickness of the wafer is sent to the control unit 16 and stored in the storage unit 20.

Note that the measurement of the thicknesses of a wafer can be performed using other various measurement devices; alternatively, parameters having a correlation with the wafer thicknesses may be measured to calculate the thickness of the wafer.

Next, as illustrated in FIG. 2, in this embodiment, an index Xp is calculated by integrating the thicknesses measured at the plurality of measurement points in the wafer by the first calculation unit (Step S103 to Step S105 below).

Specifically, the index Xp can be calculated in the following manner.

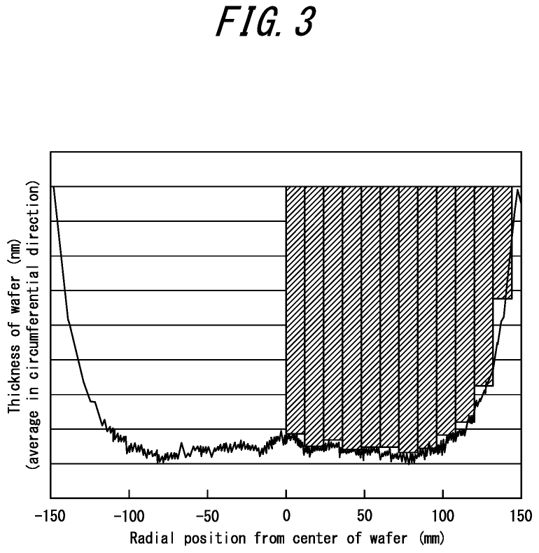

Here, FIG. 3 is a diagram illustrating the relationship between the radial positions of the measurement points from the center of the wafer, at which the thicknesses of the wafer are measured, and the thicknesses of the wafer obtained by averaging the thicknesses of the wafer in the circumferential direction. In FIG. 3, on the horizontal axis, one side of the radial direction of the wafer is the plus side, and the opposite side is the minus side.

As illustrated in FIG. 2 and FIG. 3, in this embodiment, the thicknesses of the wafer measured at a plurality of measurement points at the same radial distance from the center of the wafer are integrated (averaged in this example) in the circumferential direction of the wafer (Step S103: part of the pre-polishing index calculation step).

Thus, as illustrated in FIG. 3, the wafer shape (a shape indicating the relationship between the position in the radial direction of the wafer and the thickness of the wafer) in the case where the thicknesses of the wafer are averaged in the radial direction of the wafer can be determined.

Next, as illustrated in FIG. 2, in this embodiment, the differences between the thicknesses obtained by averaging the thicknesses in the circumferential direction of the wafer and a predetermined reference thickness are calculated (Step S104: part of the pre-polishing index calculation step).

The predetermined reference thickness is the average thickness of the thicknesses of the measurement points in the entire region ranging in the circumferential direction from a radial region from the position of 2 mm inside the wafer outer edge in the radial direction of the wafer to the position of 10 mm inside the wafer outer edge in the radial direction of the wafer in this example. Alternatively, the predetermined reference thickness may be the average, the maximum, or the minimum of the thicknesses of the wafer in the other region or may be set as appropriate. Alternatively, the averages of the thicknesses in the circumferential direction of the wafer may be directly used without calculating the difference using the predetermined reference thickness (Step S104 may be skipped).

In this embodiment, Step S104 is performed subsequent to Step S103 above; however, the disclosed method is not limited to this order, and the difference may be calculated first, and the differences may be integrated (averaged) in the circumferential direction of the wafer, or the calculations may be performed simultaneously.

Next, as illustrated in FIG. 2 and FIG. 3, in this embodiment, an index Xp is found by further integrating the above differences in the radial directions of the wafer (Step S105: part of the pre-polishing index calculation step).

Specifically, as illustrated in FIG. 3, the index Xp found by integrating the differences calculated in Step S105 above in the radial directions of the wafer is calculated.

For the sake of brevity, FIG. 3 illustrates rectangles each indicated by the product of a scale interval of the horizontal axis being set to 12.5 mm and the average thickness of the wafer in the circumferential direction on the vertical axis only on one side of the radial direction of the wafer (plus side).

In practice, in this example, the index Xp can be calculated as the sum of the areas of the rectangles each defined by 1 mm on the horizontal axis and the thickness of the wafer on the vertical axis.

In the above example, the index Xp is calculated by integrating (averaging) the thicknesses of the wafer measured at the measurement points in the circumferential direction of the wafer and further integrating the obtained values in the radial directions of the wafer; alternatively, the index Xp may be calculated by integrating (averaging) the thicknesses of the wafer measured at the measurement points in the radial directions of the wafer and further integrating the obtained values in the circumferential direction of the wafer.

Yet alternatively, an average may be calculated by dividing the above index Xp, for example, by the number of the measurement points, and the average may be used as an index Xp.

Further, in the above embodiment, a coordinate axis in the radial direction of the wafer and a coordinate axis in the circumferential direction of the wafer are set as two coordinate axes in the plane of the wafer, and the index Xp is determined by integrating the thicknesses of the wafer measured at the measurement points in the circumferential direction of the wafer and further integrating the obtained values in the radial directions of the wafer; alternatively, for example, rectangular coordinates in the plane of the wafer (for example, an x-axis and a y-axis orthogonal to the x-axis) may be set, and the index Xp may be determined by integrating (including averaging) the thicknesses of the wafer measured at the measurement points on the x-axis and further integrating (including averaging) the obtained values on the y-axis, or integrating (including averaging) the thicknesses on the y-axis and further integrating the obtained values on the x-axis.

In this case, the measurement points may for example be set at regular intervals of 1 mm on the x-axis and the y-axis.

Note however that the above intervals are not necessarily 1 mm, and may be variously set depending on the diameter of the wafer, or the like. Further, the measurement points are preferably set to be positioned at regular intervals on the x-axis and/or the y-axis; however, the measurement points may be set at irregular intervals on one or both of the x-axis and the y-axis.

Again, the differences can be calculated using or without using the predetermined reference thickness. Yet again, an average may be calculated by dividing the above index Xp for example by the number of the measurement points, and the average may be used as an index Xp.

After double-side polishing of the first batch is finished, next, as illustrated in FIG. 2, whether batch processing is to be terminated or not is determined by the determination unit of the control unit 16 (Step S106). This determination can use for example the index Xp calculated as described above and a predetermined threshold value of the index.

Note that when double-side polishing of the first batch is not performed, batch processing is not usually terminated, thus Step S106 is skipped and the process can proceed to Step S107 described below. Note however that even when double-side polishing of the first batch is not performed, the determination in Step S106 may be performed and the process can proceed to Step S107 described below depending on the determination result.

When batch processing is determined not to be terminated in Step S106, next, as illustrated in FIG. 2, in this embodiment, a target polishing time Tt of the current batch is calculated by the second calculation unit using a predetermined prediction formula that is a relation of the target polishing time Tt of the current batch, the index Xp calculated in the pre-polishing index calculation step, and an index Xt set as a target in the last batch (Step S107: target polishing time calculation step).

The above predetermined prediction formula can be given by, for example, (Equation 1) below.

A1×Tt^{α}=A2×Xp^{β}+A3×Xt^{γ}+A4, (Equation 1)

where each of A1, A2, A3, A4, α, β, and γ is one of a coefficient found by regression analysis and a predetermined coefficient determined previously, and

at least one of A1, A2, A3, A4, α, β, and γ is a coefficient found by regression analysis.

The prediction formula is not limited to the above example and may use various formulae. For example, for brevity, (Equation 2) below may be used.

Tt=B1×Xp+B2×Xt+B3, (Equation 2)

where each of B1, B2, and B3 is one of a coefficient found by regression analysis and a predetermined coefficient determined previously, and

at least one of B1, B2, and B3 is a coefficient found by regression analysis.

Note that in the first batch, an index Xt within a predetermined range (for example, a range determined from the specifications) may be set instead of the index Xt set as a target in the last batch, for example, based on the previous values or the like. In each of the second and subsequent batches, an index set as a target in the last batch may be used.

For the coefficients in the above prediction formulae (for example, (Equation 1) or (Equation 2)), predetermined coefficients determined previously may be set as appropriate using, for example, the previous values or the like in the past batch processing.

Further, in the first batch, the coefficients found by regression analysis are set as appropriate based on previous values or the like, and in the second and subsequent batches, the coefficients can be determined in a regression analytic manner using the above prediction formulae (for example, (Equation 1) or (Equation 2)) on the coefficients in the first batch.

The target polishing time Tt of the current batch can be calculated using the above prediction formulae (for example, (Equation 1) or (Equation 2)) with the predetermined coefficients previously determined and the coefficients found by regression analysis that are determined as described above.

Next, as illustrated in FIG. 2, double-side polishing is performed on the wafer while controlling the double-side polishing by the control unit 16 using the target polishing time Tt calculated in the target polishing time calculation step (Step S107) (Step S108: a double-side polishing step).

Specifically, after the target polishing time Tt is calculated, the control unit 16 rotates the upper plate 2, the lower plate 4, the sun gear 8, and the internal gear 10. Thus, double-side polishing of the wafer is started.

In the double-side polishing, the wafer is held by the carrier plate 12 provided with one or more retainer openings each for holding a wafer, the wafer is sandwiched between the rotating plates 6 consisting of the upper plate 2 and the lower plate 4, the rotating plates 6 and the carrier plate 12 are relatively rotated by the rotation of the sun gear 8 provided at a center portion of the rotating plates 6 while supplying a polishing slurry to the polishing pads from the slurry supply mechanism 14 and the rotation of the internal gear 10 provided on the circumference of the rotating plates 6, thereby double-side polishing both surfaces of the wafer using the calculated target polishing time Tt.

The double-side polishing of the wafer is finished by terminating the rotation of the upper plate 2, the lower plate 4, the sun gear 8, and the internal gear 10 by the control unit 16.

The polishing time for the double-side polishing in this case may be the calculated polishing time Tt as it is, or may be a polishing time obtained by adjusting the calculated target polishing time Tt (for example, a correction coefficient is added, multiplied, etc.).

Next, once the spectral interference displacement sensing device as the measurement unit 18 receives the information about the end of double-side polishing from the control unit 16, the process proceeds to the next batch; and Step S102 is performed again for the double-side polished wafer, and Step S102 to Step S106 are repeated. In Step S106, the above steps are repeated until the determination unit of the control unit 16 determines to terminate batch processing, and the batch processing is terminated when the determination unit determines to terminate the batch processing (Step S109).

With the double-side polishing method for a work and the double-side polishing apparatus for a work, according to the embodiment of this disclosure, described above, the variation of the GBIR values of works between batches after polishing can be controlled.

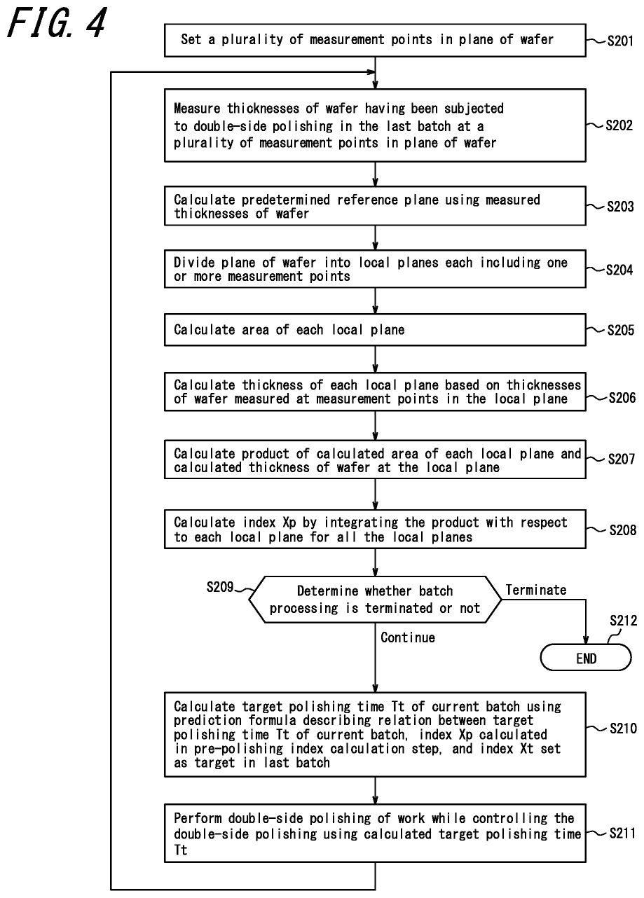

FIG. 4 is a flowchart illustrating a double-side polishing method for a work, according to another embodiment of this disclosure.

First, as in the embodiment illustrated in FIG. 2, a plurality of measurement points are set in the plane of the wafer (Step 201), and the thicknesses of the wafer are measured at the plurality of measurement points in the plane of a wafer having been subjected to double-side polishing in the last batch (Step S202: part of a pre-polishing index calculation step). The details of Step S201 and Step S202 are similar to those in Step S101 and Step S102 in the embodiment illustrated in FIG. 2, so the description will not be repeated.

Next, in this embodiment, an index Xp is calculated in the following manner.

In this embodiment, first, the plane of the wafer is divided into a plurality of local planes each including one or more measurement points, and the thickness of each local plane of the wafer is calculated based on the thicknesses of the wafer measured at the measurement points in the local planes (Step S203 to Step S206 below).

This calculation can be performed by the first calculation unit.

Specifically, as illustrated in FIG. 4, in this embodiment, first, a predetermined reference plane is calculated using the measured thicknesses of the wafer (Step S203: part of the pre-polishing index calculation step).

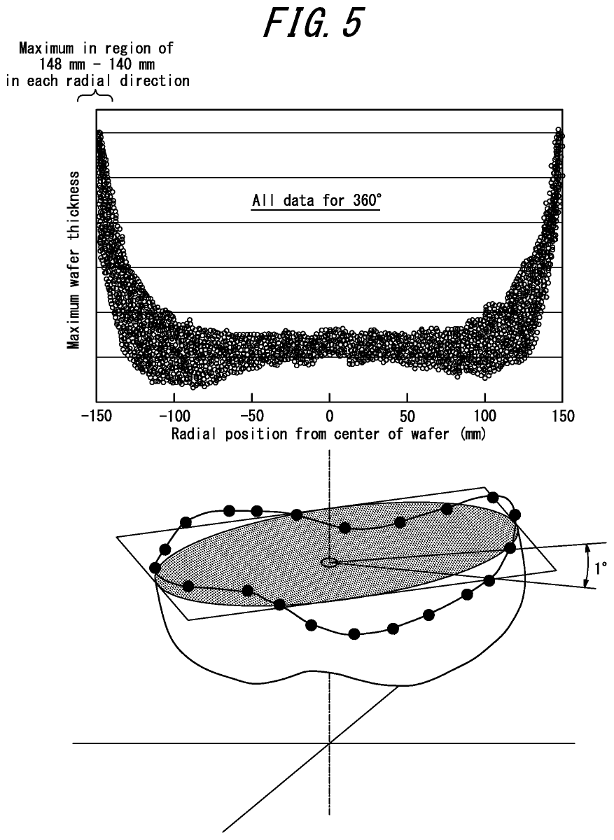

Here, FIG. 5 is a diagram illustrating a method of calculating the reference plane.

As illustrated in FIG. 5, in this example, of the measurement points in a circumferential direction of the wafer (in this example, the measurement points are set at regular intervals of 1° in the circumferential direction, so that the measurement points are set in 360 directions), the maximum values in the wafer thicknesses of a region of radial distances having an absolute value of 140 mm to 148 mm in the radial directions from the center of the wafer is selected, and a reference plane is calculated using the maximum thickness of the 360 thicknesses of the wafer such that the error is minimum in the plane including the 360 points.

For brevity, FIG. 5 illustrates plots of only 21 points in the circumferential direction; in practice, the maximum value of the 360 points in the circumferential direction are used in this example.

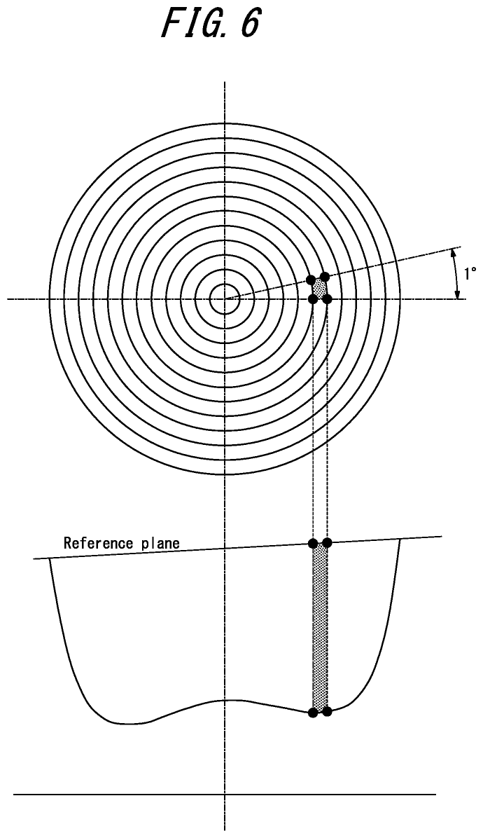

Here, FIG. 6 is a diagram illustrating a method of calculating the wafer thickness of each local plane.

Next, as illustrated in FIG. 4 and FIG. 6, in this embodiment, the plane of a wafer is divided into a plurality of local planes each including one or more measurement points (Step S204: part of the pre-polishing index calculation step).

As described above, in this example, the measurement points are set at regular intervals of 1 mm in the radial directions of the wafer, and at regular intervals of 1° in the circumferential direction of the wafer (as with the embodiment illustrated in FIG. 2).

Further, in this example, as illustrated in FIG. 6, four measurement points that are most adjacent to each other in the circumferential direction and the radial direction of the wafer are taken, and the plane of the wafer is divided into 360×150×2=108000 local planes (each enclosed by each such four measurement points) including the four measurement points. However, local planes each including the center of the wafer include three measurement points (one of them is the center of the wafer) (and are each enclosed by the three measurement points).

Next, as illustrated in FIG. 4, in this embodiment, the area of each local plane is calculated (Step S205: part of the pre-polishing index calculation step).

Next, as illustrated in FIG. 4, in this embodiment, the thicknesses of the wafer at the local planes are calculated based on the wafer thicknesses measured at the measurement points included in the local planes (Step S206: part of the pre-polishing index calculation step).

In this example, four measurement points (three in the case where the center of the wafer is included in the measurement points) are included in each local plane. Further, the average of the thicknesses of the wafer measured at the four (three in the case where the center of the wafer is included in the measurement points) measurement points with reference to the reference plane calculated in Step S203 can be calculated as the thickness of the wafer at each local plane.

Next, as illustrated in FIG. 4, in this embodiment, the calculated thicknesses of the wafer at the local planes are integrated in the plane of the wafer to calculate the index Xp (Step S207 and Step S208 below).

Specifically, the product of the area of each local plane calculated in Step S205 and the thickness of the wafer at the local plane calculated in Step S206 is calculated (Step S207: part of the pre-polishing index calculation step).

Next, as illustrated in FIG. 4, in this embodiment, the above product of each local plane is integrated for all the local planes to calculate the index Xp (Step S208: part of the pre-polishing index calculation step).

As described above, the index Xp can also be calculated by the embodiment illustrated in FIG. 4.

Next, in this embodiment, as illustrated in FIG. 4, whether batch processing is terminated or not is determined by the determination unit in the control unit 16 (Step S209). When batch processing is determined not to be terminated, next, as illustrated in FIG. 4, in this embodiment, a target polishing time Tt of the current batch is calculated by the second calculation unit using a predetermined prediction formula that is a relation of the target polishing time Tt of the current batch, the index Xp calculated in the pre-polishing index calculation step, and an index Xt set as a target in the last batch (Step S210: a target polishing time calculation step). Next, as illustrated in FIG. 4, double-side polishing is performed on the wafer while controlling the double-side polishing by the control unit 16 using the target polishing time Tt calculated in the target polishing time calculation step (Step S210) (Step S211: double-side polishing step). The process then proceeds to the next batch, and Step S202 is performed again for the double-side polished wafer, and Step S202 to Step S209 are repeated. In Step S209, the above steps are repeated until the determination unit of the control unit 16 determines to terminate batch processing, and the batch processing is terminated when the determination unit determines to terminate the batch processing (Step S211). The details of Step S209 to Step S212 are similar to those in Step S106 to Step S109 in the embodiment illustrated in FIG. 2, so the description will not be repeated.

In the embodiment illustrated in FIG. 4, the method of determining the above reference plane is only an example, and other various methods can be used. For example, in the above example, the maximum values in the wafer thicknesses of a region of radial distances having an absolute value of 140 mm to 148 mm in the radial directions from the center of the wafer is used; alternatively, the minimum value or the average thereof may be used. Still alternatively, the maximum value, the minimum value, or the average for another region may be used. Alternatively, the reference plane is not necessarily calculated, and Step S203 may be skipped.

Further, in the embodiment illustrated in FIG. 4, each local plane can be variously taken, and in the above example, local planes each including four measurement points that are most adjacent to each other in the circumferential direction and the radial directions of the wafer (enclosed by the four measurement points) are used; alternatively, for example, local planes each enclosed by three measurement points forming a triangle in plan view may be used, or the local planes may be defined such that one measurement point is surrounded by the perimeter of each local plane (each local plane include only one measurement point). Further, when the wafer plane is divided into local planes, the group of the local planes may only be distributed uniformly in 80% or more of the whole area of the wafer, and the entire wafer plane is not necessarily divided.

Further, in the above example, the calculation is performed using the average for four points as the thickness of the wafer at each local plane; alternatively, the calculation may be performed using another value such as the maximum value, the minimum value, etc. When only one measurement point is included in a local plane, the thickness of the wafer measured at the measurement point may be directly used as the thickness of the wafer at the local plane.

In the embodiment illustrated in FIG. 4, in the above example, Step S203 is performed before Step S204 and Step S205; alternatively, Step S203 may be performed after or at the same time as Step S204 and Step S205. Further, in the embodiment illustrated in FIG. 4, in the above example, Step S205 is performed before S206; alternatively, Step S205 may be performed after or at the same time as Step S206.

Also with the double-side polishing method for a work and the double-side polishing apparatus for a work, according to the another embodiment of this disclosure, described above, the variation of the GBIR values of polished works between batches can be controlled.

Examples of this disclosure will now be described; however, this disclosure is not limited to the Examples in any way.

### EXAMPLES

To confirm the advantageous effect of this disclosure, experiments were performed using simulation as described below.

### Example 1

(1) First, for polishing records of 1000 wafers, a profile of predicted values (target polishing time Tt) calculated using the prediction formula, and polishing records (indices after polishing and GBIR values) was created.
(2) In Example 1, the index of the embodiment illustrated in FIG. 2 was used as an index. Specifically, when measurement points were set at regular intervals of 1° in a circumferential direction of a wafer and at regular intervals of 1 mm in the radial directions of the wafer, the measured thicknesses of the wafer were averaged in the circumferential direction and then integrated in the radial direction, and the resultant value was used as an index (“First index” in Table 1). A target index and an initial value of the index for the first batch process were set.
(3) In the prediction formula described above, coefficients were previously set, and a target polishing time for the next batch was calculated based on the next batch using the target index in (2) above as an index Xp and the initial value of the index in (2) above as an index Xt.
(4) In this example, a GBIR value was found from a calculated target polishing time in the following manner without performing double-side polishing based on the calculated target polishing time. First, a proportionality coefficient between the calculated index and the target polishing time (“calculated index”/“target polishing time”) was previously set, and the target polishing time calculated in (3) was multiplied by this proportionality coefficient.
(5) Thus, the calculated index was calculated backwards from the calculated target polishing time.
(6) The calculated index was searched from the profile of (1), and a record linked to the index was selected.
(7) This record was stored as a result of the index of this time.
(8) A GBIR value linked to the result of this time was also stored separately.
(9) With the initial values being replaced with the result of (7), (3) to (8) were repeated 10000 times.
(10) The standard deviation for the 10000 times was calculated.

### Example 2

Simulation was performed in the same manner as in Example 1, except that the index of the embodiment illustrated in FIG. 4 was used as an index. Specifically, in Example 2, when the measurement points were set at regular intervals of 1° in the circumferential direction of the wafer and at regular intervals of 1 mm in the radial directions of the wafer, the maximum values in the wafer thicknesses of a region of radial distances having an absolute value of 140 mm to 148 mm in the radial directions from the center of the wafer was selected, and a reference plane was calculated using the maximum wafer thickness of the 360 thicknesses of the wafer so that the error was minimum in the plane including the 360 points. Further, the thicknesses of the wafer at local planes each including four (three when the center of the wafer was included in the measurement points) measurement points that were most adjacent to each other in the circumferential direction and the radial direction of the wafer (enclosed by the four (three when the center of the wafer was included in the measurement points) measurement points) were each found as the average thickness with reference to the reference plane formed by the four points, and the thicknesses of the wafer at the local planes were integrated in the plane of the wafer to be used as an index (“Second index” in Table 1).

### Comparative Example

Simulation was performed in the same manner as in Examples 1 and 2, except that the GBIR was used as an index. The specific procedure is described below.

(1) First, for polishing records of 1000 wafers, a profile of predicted values (target polishing time Tt) calculated using the prediction formula, and polishing records (GBIR values) was created.
(2) In Comparative Example, GBIR was used as an index. A target GBIR and an initial value of the GBIR for the first batch process were set.
(3) In the prediction formula described above, coefficients were previously set, and a target polishing time for the next batch was calculated based on the prediction formula using the target GBIR in (2) above as an index Xp and the initial value of the GBIR in (2) above as an index Xt.
(4) Also in Comparative Example, a GBIR value was found from the calculated target polishing time in the following manner without performing double-side polishing based on the calculated target polishing time. First, a proportionality coefficient between the calculated GBIR and the target polishing time (“calculated GBIR”/“target polishing time”) was previously set, and the target polishing time calculated in (3) was multiplied by this proportionality coefficient.
(5) Thus, the calculated GBIR was calculated backwards from the calculated target polishing time.
(6) The calculated index was searched from the profile of (1), and a record linked to the index was selected.
(7) This record (GBIR) was stored as a result of this time.
(8) With the initial values being replaced with the result of (7), (3) to (7) were repeated 10000 times.
(9) The standard deviation for the 10000 times was calculated.

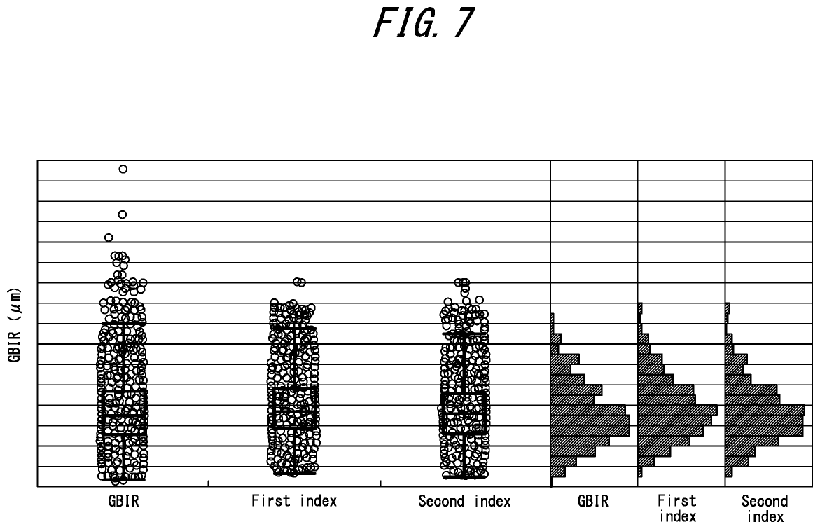

The evaluation results are given in FIG. 7 and Table 1 below. FIG. 7 is a diagram illustrating the relationship between the indices and the GBIR.

TABLE 1

| | | Number of | Standard |
|---|---|---|---|
| | Index | samples | deviation |
| Comparative | GBIR | 9964 | 0.016593 |
| Example | | | |
| Example 1 | First index | 9977 | 0.015448 |
| Example 2 | Second index | 9971 | 0.015182 |

As given in FIG. 7 and Table 1, in Examples 1 and 2 using a predetermined index, the variation of the GBIRs of the polished wafers between batches was smaller as compared with that in Comparative Example using the GBIR as an index.

### REFERENCE SIGNS LIST

100: Double-side polishing apparatus;
2: Upper plate;
4: Lower plate;
6: Rotating plates;
8: Sun gear;
10: Internal gear;
12: Carrier plate;
14: Slurry supply mechanism;
16: Control unit;
18: Measurement unit; and
20: Storage unit.

1. A method of double-side polishing a work, the method comprising:
a pre-polishing index calculation step of measuring thicknesses of a work having been subjected to double-side polishing in a last batch at a plurality of measurement points in a plane of the work using a measurement unit, and calculating an index Xp determined by integrating the thicknesses of the work measured at the plurality of measurement points in the plane of the work by a first calculation unit;
a target polishing time calculation step of calculating a target polishing time of a current batch by a second calculation unit using a predetermined prediction formula describing a relation between a target polishing time Tt of the current batch, the index Xp calculated in the pre-polishing index calculation step, and an index Xt set as a target in the last batch; and
a double-side polishing step of performing double-side polishing of a work while controlling the double-side polishing by a control unit using the target polishing time calculated in target polishing time calculation step.

2. The method of double-side polishing a work, according to claim 1, wherein the index Xp is determined by integrating the thicknesses of the work measured at the plurality of measurement points on one of two coordinate axes on the plane of the work and further integrating the thicknesses on the other coordinate axis.

3. The method of double-side polishing a work, according to claim 2, wherein the two coordinate axes consist of a coordinate axis in a radial direction of the work and a coordinate axis in a circumferential direction of the work, and
the index Xp is determined by integrating the thicknesses of the work measured at the plurality of measurement points in the circumferential direction of the work, and further integrating the thicknesses in radial directions of the work.

4. The method of double-side polishing a work, according to claim 1, wherein the index Xp is calculated by:
dividing the plane of the work into a plurality of local planes each including one or more of the measurement points,
calculating thicknesses of the work at the local planes based on the thicknesses of the work measured at the measurement points included in the plurality of local planes, and
integrating the calculated thicknesses of the work at the local planes in the plane of the work.

5. The method of double-side polishing a work, according to claim 4, wherein the thickness of the local planes of the work is an average of the thicknesses of the work measured at the measurement points defining the local planes.

6. The method of double-side polishing a work, according to claim 2, wherein the measurement points are positioned at regular intervals on at least one of the two coordinate axes in the plane of the work.

7. The method of double-side polishing a work, according to claim 1, wherein the predetermined prediction formula is represented by:
A1×Tt^{α}=A2×Xp^{β}+A3×Xt^{γ}+A4,
where each of A1, A2, A3, A4, α, β, and γ is one of a coefficient found by regression analysis and a predetermined coefficient determined previously, and
at least one of A1, A2, A3, A4, α, β, and γ is a coefficient found by regression analysis.

8. The method of double-side polishing a work, according to claim 1, wherein the double-side polishing step is performed using a batch-processing double-side polishing apparatus for works, the apparatus comprising: rotating plates having an upper plate and a lower plate; a sun gear provided at a center portion of the rotating plates; an internal gear provided on a periphery of the rotating plates; and a carrier plate having one or more retainer openings each for holding a work, the carrier plate being provided between the upper plate and the lower plate, with a polishing pad being attached to each of a lower surface of the upper plate and an upper surface of the lower plate.

9. The method of double-side polishing a work, according to claim 8, wherein the double-side polishing step comprises a step of polishing both surfaces of the work while supplying a polishing slurry to the polishing pads and relatively rotating the rotating plates and the carrier plate for the calculated polishing time of the current batch.

10. The method of double-side polishing a work, according to claim 1, wherein the work is a wafer.

11. A double-side polishing apparatus for a work, the apparatus comprising: rotating plates having an upper plate and a lower plate; a sun gear provided at a center portion of the rotating plates; an internal gear provided on a periphery of the rotating plates; a carrier plate having one or more retainer openings each for holding a work, the carrier plate being provided between the upper plate and the lower plate; with a polishing pad being attached to each of a lower surface of the upper plate and an upper surface of the lower plate, the apparatus further comprising:
a measurement unit for measuring thicknesses of the work having been subjected to double-side polishing in a last batch;
a first calculation unit calculating an index Xp by integrating the measured thicknesses of the work in the plane of the work;
a second calculation unit calculating a target polishing time Tt of a current batch, using a predetermined prediction formula describing a relation between the target polishing time Tt of the current batch, the index Xp, and an index Xt set as a target in the last batch; and
a control unit controlling double-side polishing of the work using the calculated target polishing time Tt.

12. The method of double-side polishing a work, according to claim 3, wherein the measurement points are positioned at regular intervals on at least one of the two coordinate axes in the plane of the work.

13. The method of double-side polishing a work, according to claim 4, wherein:
the index Xp is determined by integrating the thicknesses of the work measured at the plurality of measurement points on one of two coordinate axes on the plane of the work and further integrating the thicknesses on the other coordinate axis, and
the measurement points are positioned at regular intervals on at least one of the two coordinate axes in the plane of the work.

14. The method of double-side polishing a work, according to claim 5, wherein:
the index Xp is determined by integrating the thicknesses of the work measured at the plurality of measurement points on one of two coordinate axes on the plane of the work and further integrating the thicknesses on the other coordinate axis, and
the measurement points are positioned at regular intervals on at least one of the two coordinate axes in the plane of the work.

15. The method of double-side polishing a work, according to claim 2, wherein the predetermined prediction formula is represented by:
A1×Tt^{α}=A2×Xp^{β}+A3×Xt^{γ}+A4,
where each of A1, A2, A3, A4, α, β, and γ is one of a coefficient found by regression analysis and a predetermined coefficient determined previously, and
at least one of A1, A2, A3, A4, α, β, and γ is a coefficient found by regression analysis.

16. The method of double-side polishing a work, according to claim 3, wherein the predetermined prediction formula is represented by:
A1×Tt^{α}=A2×Xp^{β}+A3×Xt^{γ}+A4,
where each of A1, A2, A3, A4, α, β, and γ is one of a coefficient found by regression analysis and a predetermined coefficient determined previously, and
at least one of A1, A2, A3, A4, α, β, and γ is a coefficient found by regression analysis.

17. The method of double-side polishing a work, according to claim 4, wherein the predetermined prediction formula is represented by:
A1×Tt^{α}=A2×Xp^{β}+A3×Xt^{γ}+A4,
where each of A1, A2, A3, A4, α, β, and γ is one of a coefficient found by regression analysis and a predetermined coefficient determined previously, and
at least one of A1, A2, A3, A4, α, β, and γ is a coefficient found by regression analysis.

18. The method of double-side polishing a work, according to claim 5, wherein the predetermined prediction formula is represented by:
A1×Tt^{α}=A2×Xp^{β}+A3×Xt^{γ}+A4,
where each of A1, A2, A3, A4, α, β, and γ is one of a coefficient found by regression analysis and a predetermined coefficient determined previously, and
at least one of A1, A2, A3, A4, α, β, and γ is a coefficient found by regression analysis.

19. The method of double-side polishing a work, according to claim 6, wherein the predetermined prediction formula is represented by:
A1×Tt^{α}=A2×Xp^{β}+A3×Xt^{γ}+A4,
where each of A1, A2, A3, A4, α, β, and γ is one of a coefficient found by regression analysis and a predetermined coefficient determined previously, and
at least one of A1, A2, A3, A4, α, β, and γ is a coefficient found by regression analysis.

20. The method of double-side polishing a work, according to claim 2, wherein the double-side polishing step is performed using a batch-processing double-side polishing apparatus for works, the apparatus comprising: rotating plates having an upper plate and a lower plate; a sun gear provided at a center portion of the rotating plates; an internal gear provided on a periphery of the rotating plates; and a carrier plate having one or more retainer openings each for holding a work, the carrier plate being provided between the upper plate and the lower plate, with a polishing pad being attached to each of a lower surface of the upper plate and an upper surface of the lower plate.
